(19) United States
(12) Patent Application Publication
(10) Pub. No.: US 2017/0370693 A1
(43) Pub. Date: Dec. 28, 2017

(54) ELECTRICAL COMPONENT HAVING A SENSOR SEGMENT COMPOSED OF CONCRETE, METHOD FOR PRODUCING SAME, AND USE OF SAME

(71) Applicant: KENNWERT RD GMBH, Kassel (DE)

(72) Inventors: Thorsten KLOOSTER, Berlin (DE); Jan JURASCHEK, Kassel (DE); Pat TAYLOR, Gießen (DE)

(73) Assignee: KENNWERT RD GMBH, Kassel (DE)

(21) Appl. No.: 15/544,458

(22) PCT Filed: Jan. 19, 2016
(86) PCT No.: PCT/EP2016/051035

§ 371 Date: Jul. 18, 2017

(30) Foreign Application Priority Data
Jan. 19, 2015 (DE) 10 2015 100 711.8

(51) Int. Cl. G01B 7/14; H03K 17/96; G01N 27/04; H03K 17/955; G01M 5/00; H04W 4/04

(52) U.S. Cl. CPC G01B 7/14; H03K 17/955; G01M 5/0083; H03K 17/962; G01M 5/0041; G01N 27/041; H03K 17/9645; H04W 4/04

(57) ABSTRACT

The invention describes an electrical component (10) which at least comprises a section (12) configured as a sensor (sensor section) made of concrete and which contains electrically conductive aggregates (22) which are present in a region (24) near the surface of at least one outer surface (20) of the section (12) in a higher spatial density than in the remaining section (12). In addition, a method for its production and a use of the component (10) are described.

The invention relates to an electrical component which at least comprises a section made of concrete configured as a sensor, and a method for producing such a component and its use.

CN 101 602 591 B describes a concrete mixture which provides pressure-dependent conductivity when hardened. It can be used to produce a scale for heavy loads.

It is an object of the invention to make a sensor element which is extremely robust and long-lasting, and to specify its production and advantageous applications.

This object is achieved by an electrical component which at least comprises a section (sensor section) made of concrete configured as a sensor which contains electrically conductive aggregates which are present in a higher spatial density on a region near the surface of at least one outer surface of the sensor section than in the remaining section. According to the invention, the electrically conductive aggregates are unevenly distributed, and actually with a density that decreases away from the region near the surface. This is unusual in that, in the production of conventional components made of concrete, an evenly constructed grain structure with a homogeneous distribution of the aggregates in the matrix of water and cement is sought. Its homogeneity is already attended to when mixing, but also when introducing the concrete into a formwork and when compacting. In principle, the concrete sensor also works with a continuous distribution of the electrically conductive aggregates. According to the invention, the electrically conductive aggregates are present at least at an outer surface of the sensor-configured section of the component in a high concentration and there on the surface thereof or near the surface. In contrast to all other aggregates of the component made of concrete, the electrically conductive aggregates advantageously have a discontinuous distribution while the remaining aggregates have a substantially continuous or homogeneous distribution in the component. The electrically conductive aggregates can be present in a range of values for the concentration of 2, 4, 5, 7 or 9 to approx. 10% by mass. Their density or concentration is advantageously chosen such that they do not adversely affect the desired and required properties of the concrete section, for example, its tensile and compressive strength. A further criterion for the concentration may be the cost of the electrically conductive aggregate.

According to the invention, in principle, all types of concrete can be used for the production of the sensor section: Both normal concretes of all qualities and special concretes, fiber or textile concretes, glass foam, light, polymer concrete, high-strength, water-impermeable or translucent concrete or other high-performance concrete can be used, if and to the extent that their properties are not impaired by the addition of the electrically conductive aggregates.

With the increased spatial density or concentration of electrically conductive aggregates on the surface of the sensor section, the component has a significantly higher electrical conductivity there than in the remaining concrete section. The conductivity of the section made of concrete is therefore discontinuous in a section running perpendicular to the surface, namely corresponding to the distribution of the electrically conductive aggregates. The invention is directed to use the conductivity of the concrete thus obtained primarily for the transport of current, that is, for the configuration of a current conductor. This is because over great distances, concrete is lossy as a conductor. Rather, the invention pursues the principle of using the proportionally weak conductivity of the concrete component for the transmission of information, that is, the conversion of an information lead, by detecting a change in the voltage, the capacitance or the resistance in the conductive sensor section.

The invention thus makes possible the configuration of proximity-sensitive or contact-sensitive concrete surfaces, which allows the configuration of wall surfaces according to the “touchscreen principle”. The component according to the invention can optionally be a contact sensor without mechanical components or a proximity sensor which can be operated manually. Alternatively, it can detect characteristics, in particular of a loaded component, for example, a strain, temperature or humidity change. The conductive component configured according to the invention can therefore be the basis, for example, of operating elements without mechanical components for switching and controlling the electrical current of technical building equipment (light, ventilation, heating, data etc.) and household appliances or other electronic devices such as a stereo system. The invention thus expands the possibilities of the use, the integration and the positioning of sensor surfaces and their use as switch or control elements since, in principle, they are hardly ever subject to a compulsory specific localization and can be completely integrated into a construction structure. As a result, control elements in the dimensions of conventional switches and considerable, larger operating elements, up to complete walls, can be configured as switches or control elements.

The control elements can also be constructed additively: Several components according to the invention made of conductive concrete can together form an operating surface, the behavior of which is controlled by a control unit. Moreover, components need not be arranged in a coherent manner. They can be arranged as desired over a wall surface, over several wall surfaces of the same space or distributed over a building.

In addition, the invention allows the configuration of intelligent components having integrated control functions, for example, for detecting deformations of highly stressed components or for measuring the cyclical temperature behavior of heavy components, and for detecting changes in room temperature or humidity:

According to the invention, the positive properties of concrete are extended by a sensory component as a fire-resistant, durable, high-strength building material which is largely freely configurable in terms of its external shape. Together with a computer unit which recognizes low voltage, capacity or resistance changes and can further process them to control commands, a material system results which can be operated in a manner known as so-called “touch screens”.

The incorporation of conventional location-based control elements can bring numerous disadvantages with regard to their arrangement, for example, with regard to their accessibility to children, adults or disabled persons, with regard to their durability of the mechanically stressed parts and their vulnerability to environmental influences, for example, electrical switches in damp rooms. The invention, on the other hand, can provide a fire-resistant, large area, vandalism-proof and largely moisture-insensitive actuating element. As a pure sensor element for the detection of deformation, temperature or humidity changes, it can be easily and completely unobtrusively installed and offers an equally high durability and resistance.

Its moisture-insensitivity and the possibility of using the component according to the invention for the detection of moisture changes are not contradictory. The component is not essentially moisture-insensitive, otherwise it could not detect moisture changes. Increased humidity, however, does not influence it, and may even be a positive influence. The overall behavior of the component is essentially defined by general concrete properties—relatively high to very high impermeability on the surface, especially as a visible concrete application—and the conductivity, which is increased by the aggregates, which tends to improve in dampened media.

The electric field of the weakly charged concrete elements changes as a result of contact with the surface. The change in the electric field induced by contact is effected, depending on the required signal resolution, by means of a outgoing feeder at a suitable location of the component, for example, on its rear side or via a grid of such outgoing feeders, such as metallic components in the form of pins or the like, the arrangement of which simultaneously defines, detects and localizes the location resolution of the component, and is transmitted to a signal processing unit as a signal. The signal processing unit or control unit can be freely programmed. According to its programming, the signal processing unit transmits control commands to actuators or devices such as, for example, lamps, servomotors of shading devices, controls of air conditioning systems and the like.

The signal processing unit is usually located outside the component. Their arrangement can be followed by structural or specialized planning considerations. It can ultimately be positioned anywhere, even in the concrete component itself. Integration into a main distribution or sub-distribution, comparable to a modern dimming unit, is practical.

According to an advantageous embodiment of the invention, the component can be configured as a capacitive, inductive or resistive sensor section:

As a capacitive sensor, the electrically conductive sensor section according to the invention be used as a plate of a capacitor, the charge of which changes as soon as, in particular, a dielectric such as the human being comes into its immediate vicinity. Direct contact is not required.

As an inductive sensor, a separate control element may be required for its operation. It builds up a magnetic field by means of a coil whose movement on its surface detects the capacitively acting sensor element. As a switching element, the inductive sensor element can require the separate operating element for switching, in that the control element causes a change in the magnetic field with sufficient proximity to the sensor element. The requirement of an operating element can thereby prevent any or unauthorized actuation of the switching element and can function according to the key-lock principle.

As a resistive sensor, a thin concrete disk having electrically conductive aggregates can be configured on an upper side or in a near-surface layer, so that a deflection of the concrete disk can be electrically sensitized as a change in resistance.

The charge (or voltage or resistance) change of the sensor section made of concrete can be determined via a detection device and processed into a control command. Thus, the component can also be adapted to different application areas and requirements and can either be operated with or without contact. The invention thus follows the principle of detecting a charge, voltage or resistance change in the sensor section and of generating switching or control signals therefrom. Thus, a lower conductivity of the component is sufficient, which is further optimized by influencing the spatial density of the electrically conductive aggregates. In addition, the switching or control element according to the invention no longer directly switches or controls the working current, which operates a lamp, a machine or the like, but a switching element which is secured from the operator and preferably protected against undesired influences.

The electrically conductive aggregates can be distributed evenly in the region of the section of concrete which is close to the surface, in both spatial directions over the extent of the surface in order to cause the same electrical reaction at any location on the surface upon approach or contact. According to a further advantageous embodiment of the invention, the electrically conductive aggregates can be unevenly distributed in a plan view on the outer surface or component surface of the section configured as a sensor. Depending on the application, they can in this case follow a regular or an irregular pattern. With a discontinuous distribution of the electrically conductive aggregates, the proximity-sensitive or touchsensitive function can also accordingly follow a certain predetermined pattern. The pattern can be provided for purely optical reasons. Alternatively, the pattern can be used for technical purposes, for example, through an only partially planar but regular arrangement, leading to a more economical use of the electrically conductive aggregates.

According to a further advantageous embodiment of the invention, the component comprises electrical interfaces, attached on or inserted into regions near the surface, to an electrical circuit, in particular to an electrical control or computer unit. The electrical interfaces or contacts may comprise electrically conductive pins, bolts, screw bolts, sleeves with internal threads, clamps, or the like. They are in contact with the area near the surface, for example, by being inserted into it, thereby establishing a conductive contact to the electrically conductive aggregates.

With their uniform distribution in the surface, the interfaces may be in a grid-like arrangement in order to enable a local resolution with regard to an actuation of the component. For example, with a grid-like arrangement of electrical interfaces at the intersection points of a grid network made of square partial surfaces, the location of an approach to or touch of the sensor section(s) can be detected, since it generally falls in one of the square partial areas of the grid. The partial surface can be localized by its four corner points. With a localization of an approach or actuation, individual or several partial surfaces of such a grid structure can be assigned certain different functions, whereby the component can provide the basis for a more complex operation. Thus, in the grid of a grid network, not only different functions can be arranged above or next to one another, such as, for example, switch functions for different lighting bodies in a lecture room. It is also possible to offer the same function in gradual gradation, whereby, for example, a dimmer function can be configured

In the case of uneven distribution of the electrically conductive aggregates in the surface, the interfaces can advantageously be oriented on a pattern which is based on the uneven distribution.

According to a further advantageous embodiment of the invention, the sensor section can have carbon, graphite, iron, metallic pigments or metal oxide as electrically conductive aggregates. Carbon can preferably be added in the form of so-called carbon nanotubes and iron as chips or steel fibers. There has already been experience with aggregates with regard to their processing and their use in concrete.

In order to be detectable even without a mechanical control element as a switch or control element arranged only partially over a building wall, the location of the sensor section according to the invention can be indicated by, for example, a colored marking on the building wall. According to a further advantageous embodiment of the invention, the sensor element can have an optically perceptible marking produced on its surface by means of the electrically conductive addition. A separate marking for the location of the sensor section per se or for the function assigned to it can thus be omitted. The marking according to the invention is in general also substantially more durable since it can not be worn away by intensive use, for example, in the public space. Metal oxides and all other substances known for the dyeing of concrete can be used as a suitable aggregate, provided they are electrically conductive. As a result, the electrically conductive aggregate has a double function, whereby the work step and the material for separate marking and thus the related costs can be omitted.

The component according to the invention can be used not only as an operating element of a switch or control element but also exclusively as a sensor for detecting variable component characteristics such as, for example, temperature, deformation or moisture. As such, it can advantageously be installed in a component to be sensed as a monolithically arranged sensor made of electrically conductive concrete. Thus, for example, it can be arranged in the tensile zone of a highly stressed concrete carrier, where the carrier is produced with a recess on the tensile zone side into which the component according to the invention is then concreted on or in. Likewise, it may be installed in another component, for example, also in a brick wall, in order to detect the change in a deformation, room moisture or temperature. The electrical resistance of the sensor section changes by a deformation, a change in a room moisture or temperature, which can be detected and evaluated by a computer unit.

Concrete offers a wide range of possible applications as a building material. The component according to the invention therefore also provides a further variety of possible applications, such as the configuration of large-area conductive components as a facing formwork, the production of thin-walled components made of conductive concrete which are integrated into larger components, the production of thin-walled components made of conductive concrete which can be freely positioned, that is, elements which are installed instead of light switch(es) or button(s), the production of control elements for conductive concrete for outdoor regions, which are very robust and long-lived, for example, an outdoor kitchen.

The object mentioned at the outset is also achieved by a method for producing a proximity-sensitive or contact-sensitive electrical component, having the following steps:
a) Preparing a concrete matrix for fresh concrete,
b) Admixing electrically conductive aggregates into the fresh concrete,
c) Introducing the fresh concrete into a formwork for the component to be produced,
d) Increasing the spatial density of at least a portion of the electrically conductive aggregates near a component surface,
e) Allowing the concrete component to harden.

The method according to the invention is not initially substantially different from the conventional concreting process, in that fresh concrete is introduced into a formwork, in which it cures. The formwork is then generally removed. The term formwork is understood to be a casting mold into which the fresh concrete is introduced to produce a concrete component. After the concrete hardens, it is usually removed. Thus, the formwork represents the negative of the concrete component. Formworks which are not removed after the concrete has hardened (so-called lost formworks) can also be other components, for example, concrete components which remain in their location in a constructional structure. A depression in a component which is filled with fresh concrete can also be a lost formwork.

Unlike conventional methods, the concrete matrix of the fresh concrete according to the invention, on the one hand, comprises electrically conductive aggregates. The time point of their admixture depends, for example, on the processability of the electrically conductive aggregates. In principle, they can be added at virtually any point in time and treated like all other aggregates. Process steps a) and b) therefore do not have to take place chronologically successively, but can also take place simultaneously.

According to the invention, on the other hand, the spatial density of at least a part of the electrically conductive aggregates in the fresh concrete is altered in such a way that at least a part of the electrically conductive aggregates are located in a defined region on a component surface or component outer surface. Thus, a part of the electrically conductive aggregates is present in an uneven distribution in the cross-section of the component in which they concentrate near or at a component surface, while they are not present in the remaining region or are hardly present, i.e., in extremely low concentration. The electrically conductive aggregates thus have an uneven distribution which is extremely unusual for a concrete matrix and generally undesirable, thus making the concrete inhomogeneous in this respect. In this way, however, after curing and after stripping, a concrete component can be obtained which in any case has a particularly high electrical conductivity on a component exterior or surface with respect to normal concrete. Thus, it can be advantageously used in the manner already described above.

According to a further advantageous embodiment of the invention, at least one part of aggregates which can be influenced by magnetization can be admixed in in step b), and a magnetic field can be established in step d) on the formwork filled with the fresh concrete prepared according to the invention. The magnetic field can be applied uniformly or non-uniformly in the surface for functional and/or optical reasons. The electrically conductive aggregates which can be magnetically influenced can be magnetically influenced in their spatial position. For this, they may be ferromagnetic, paramagnetic or diamagnetic. In the case of ferro- and paramagnetic aggregates, the magnetic field is applied on the formwork side which is closer to the future contact-sensitive surface of the concrete component. In the case of diamagnetic aggregates, on the other hand, the magnetic field is established on the opposite side of the formwork. With the establishment of the magnetic field, the magnetic and electrically conductive aggregates can be concentrated at or near a component surface, as long as they are largely free-moving in the fresh concrete, i.e., they have not set yet. The movement of the magnetic aggregates by the action of the magnetic field can still be supported by compressing the concrete, for example, through external, formwork or internal vibrators.

The magnetic field can, for example, be applied by means of permanent magnets, which can be attached directly to the formwork permanently or detachably. Alternatively, the magnetic field may be based on electromagnetism. According to an advantageous embodiment of the invention, a pulsed magnetic field can be established, which is, in particular, not continuously applied. On the one hand, the intensity of the magnetic field can be controlled via the current intensity, and on the other hand, energy can be saved by not having to permanently maintain the magnetic field. After reaching a certain concentration of the electroconductive aggregates which can be influenced magnetically, the distribution achieved is not lost again as soon as the vibrators are switched off again. In the absence of any possibility of movement, the distribution of the magnetic aggregates which have then been achieved is largely maintained.

According to a further advantageous embodiment of the invention, the electrically conductive aggregates can be unevenly distributed over the component surface in a plan view. In this way, a component surface can be achieved which has different contact sensitivity depending on location. The non-uniform distribution of the electrically conductive aggregates can be effected, for example, by applying magnetic fields of different strengths, by concreting “in two phases”, namely by introducing fresh concrete without or with a smaller proportion of conductive additive and by introducing fresh concrete with or with a higher proportion of conductive additive in a formwork. Finally, the uneven distribution of the electrical conductivity can be achieved by locally applying a conductive layer to a fresh or already hardened concrete component according to the invention with uniform distribution of the conductive aggregate. The conductive layer can be effected as a pressure or spray coating, for example, by a graphite-cement coating or as a thin shotcrete layer.

According to a further advantageous embodiment of the invention, electrical contacts are mounted before step c) into the formwork or after the step e) in the hardened concrete component. Before step c), they can advantageously be positioned and installed in the formwork so that the electrical contacts are already fixed during concreting. A finished concrete component according to the invention having a touch-sensitive surface is thus obtained after stripping. If, on the other hand, effort for the introduction of the electrical contacts into the formwork is to be avoided, they can also be mounted afterwards, for example, in a bore after stripping hardened concrete components. In this way, the concrete element can possibly be better adapted to a concrete installation situation.

According to a further advantageous embodiment of the invention, the electrical contacts can be arranged in an almost arbitrarily selected pattern, for example, in a uniform grid. Their arrangement is essentially determined according to the distribution of the electrically conductive aggregates in the concrete component. If they are distributed evenly over the contact-sensitive surface of the component, the arrangement of the electrical contacts can be selected almost arbitrarily. If, however, the aggregates are unevenly spread across the component surface, then the arrangement of the electrical contacts must also be matched so that they are not arranged in a region of too low a concentration of electrically conductive aggregates. With a uniform grid of electronic contacts, in any case, a spatial resolution can be enabled, whereby the location of an approach to the concrete component or its contact can be spatially limited and therefore can be detected more precisely.

The object mentioned at the outset is also achieved by a method for the production of a proximity-sensitive or contact-sensitive electrical component, wherein the component is concreted in two phases, namely in a first phase with a, for example, conventional concrete and in a second phase with a concrete having an electrically conductive additive. The production of a proximity-sensitive or contact-sensitive electrical component having a density of electrically conductive aggregate in the concrete component increasing towards a surface can consequently also be achieved in two or more stages by applying layers with different concentrations of electrically conductive aggregates. The application of the layers can comprise a pressure or spray coating, for example, a graphite cement coating, or a thin shotcrete coating, especially in the case of parts to be produced vertically. The method result can be considered as a facing shell of fresh concrete having a conductive additive on fresh concrete “without” conductive additive.

According to an alternative process, the proximity-sensitive or contact-sensitive component according to the invention can be produced where at least the electrical component is produced as a precast concrete part and then applied on or embedded flush in any concrete component, e.g., on almost any building wall. The entire component itself can also be produced as a precast concrete part. The electrical component as a precast concrete part can already have the necessary electrical connections, via which it is connected to a control device or household electronics. As a result, it is also suitable for retrofitting, since the retrofitting of the required electrical lines can generally also be carried out without any significant expenditure. Embedded in an existing wall, it can be used flush with the surface or deliberately with a height or depth offset in order to visually lift it off as a functional surface with respect to the remaining wall surface.

The object mentioned at the outset is also achieved by the use of an above-described electrical component or electrically conductive concrete section as a switching or control element for switching or controlling electrical current and/or for detecting variable component characteristics. This results in the above-described advantages.

The invention also provides a series of further possible applications of the electrical component according to the invention by methods for determining the position of a mobile communication device in a building having electrical components and with a central computer which stores location information of each electrical component within the building and a respective further data record for each electrical component. The method is divided into the following steps:
a) Making contact with the central computer by the communication device,
b) Requesting to actuate the electrical component,
c) Detecting an actuation of the electrical component,
d) Transferring the further data set assigned to the actuated electrical component to the communication device.

A mobile communication device is, in particular, a smartphone. The electrical components may be arranged at nearly any location within a building as long as they are installed in a position reachable by a user, e.g., with one hand. Their respective exact location within the building is known to a building's own central computer. After the communication device contacts the central computer via known conventional communication techniques, the user can touch the electrical component. The touch is detected in the manner described above and transmitted to the central computer. Thus, the location of the user of the communication device can be detected within the building independently of known, for example, GPS-supported location technologies, and communicated to the central computer. Thereupon, the central computer can transmit the further data record, which is stored to the actuated component, to the communication device. In this way, the user can be given, for example, ways to specific facilities such as breakfast rooms, spa areas or escape routes in an unknown hotel or a visitor to a museum's data to exhibits by simply touching a wall surface. The wall surface can also have several surfaces which can be distinguished from one another, to which different data are assigned and whose activation provides different information.

The principle of the invention is explained in more detail below by means of a drawing, by way of example. The drawings show:

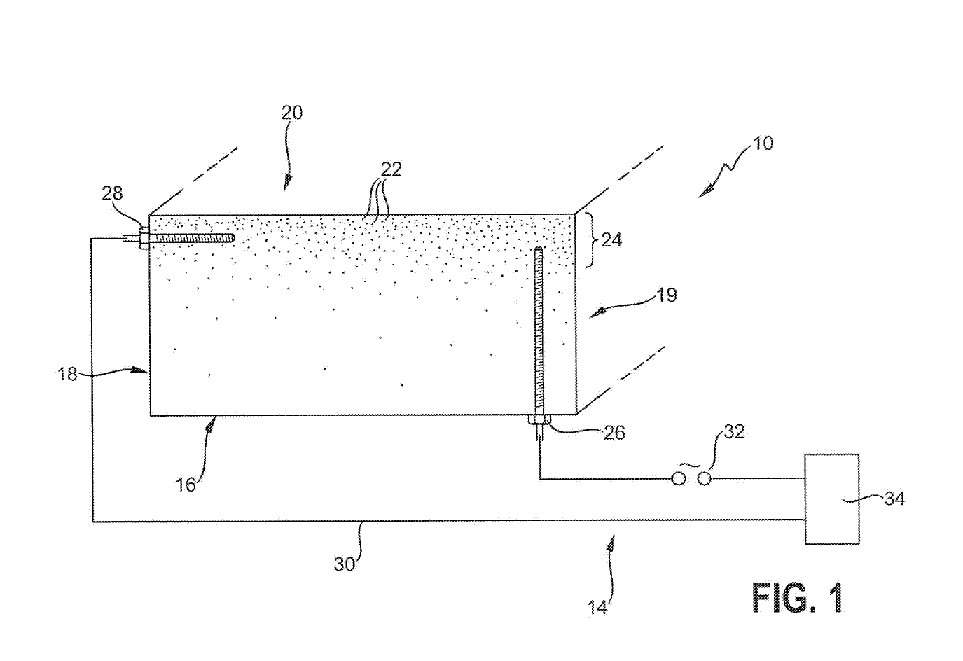

FIG. 1: a principle diagram of an electrical component according to the invention,

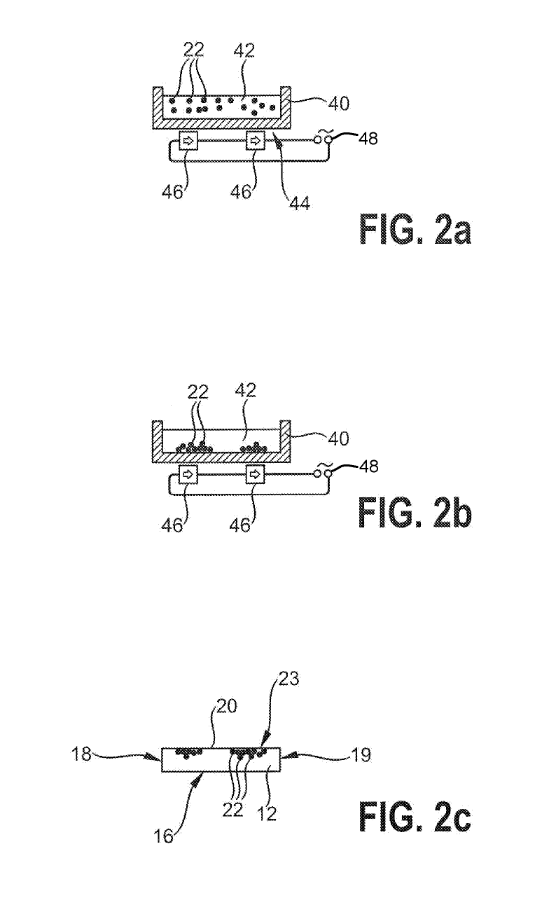

FIG. 2: a schematic diagram of the production of a sensor section according to the invention,

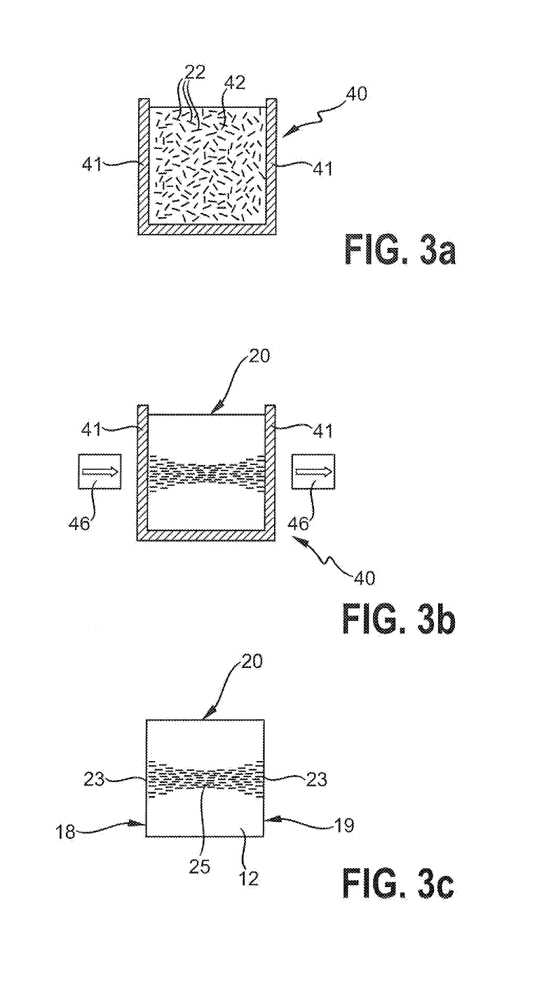

FIG. 3: an alternative method of producing a sensor section,

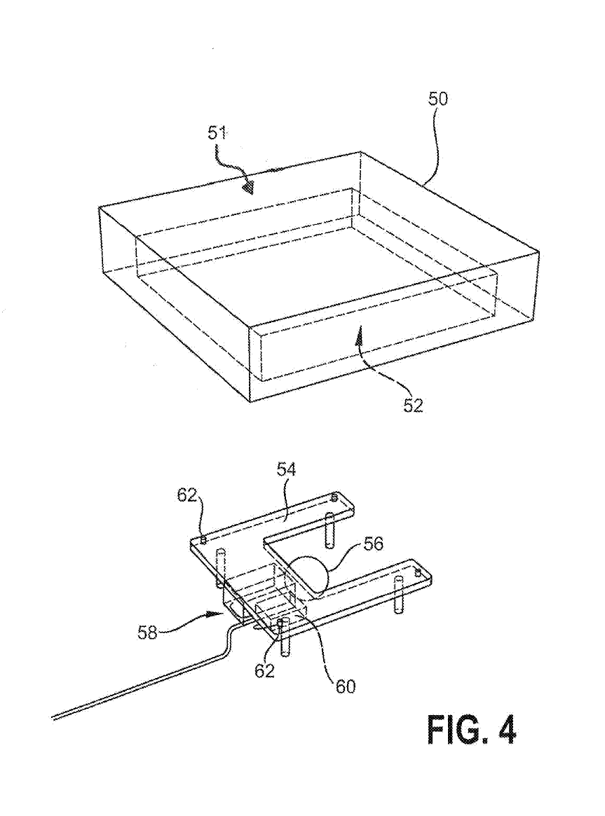

FIG. 4: an application example of the invention,

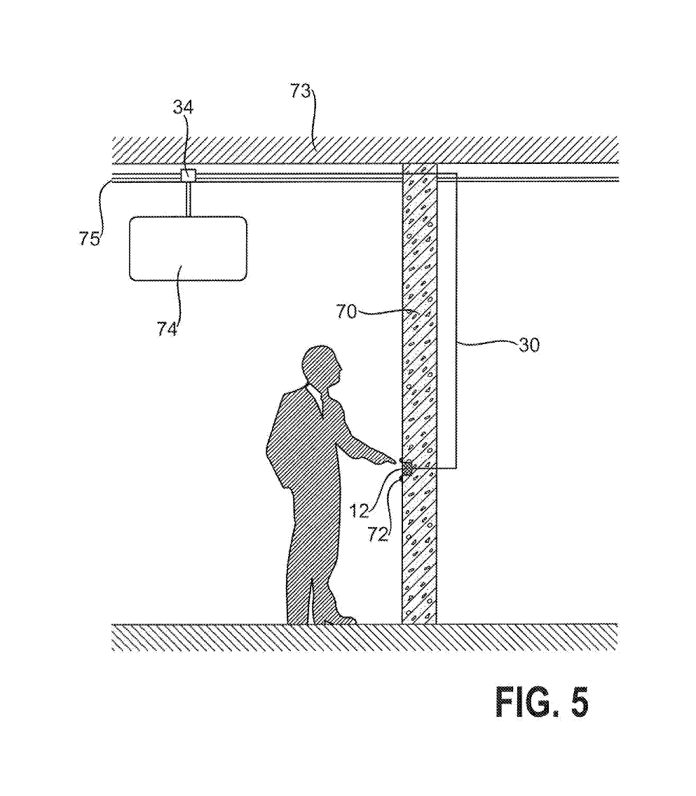

FIG. 5: a sectional view of a first embodiment of a domestic installation,

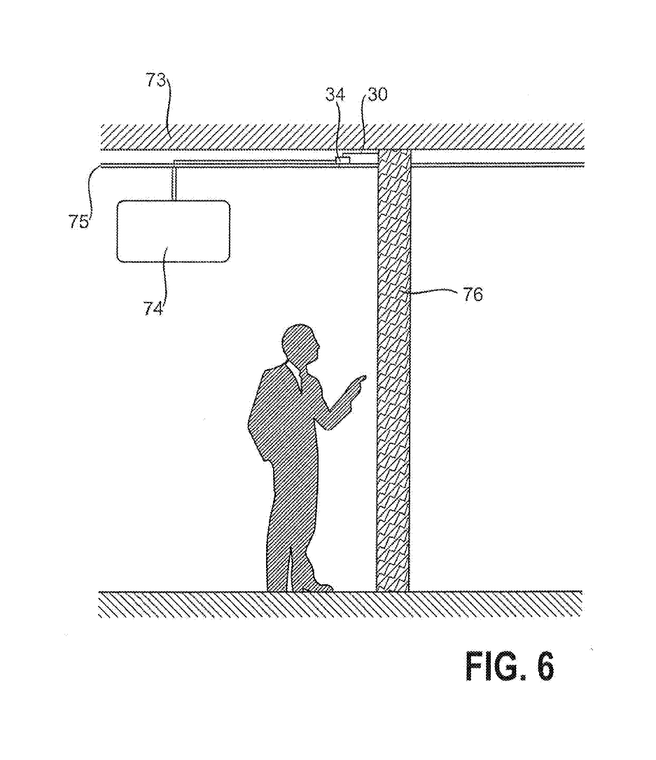

FIG. 6: an alternative embodiment to it,

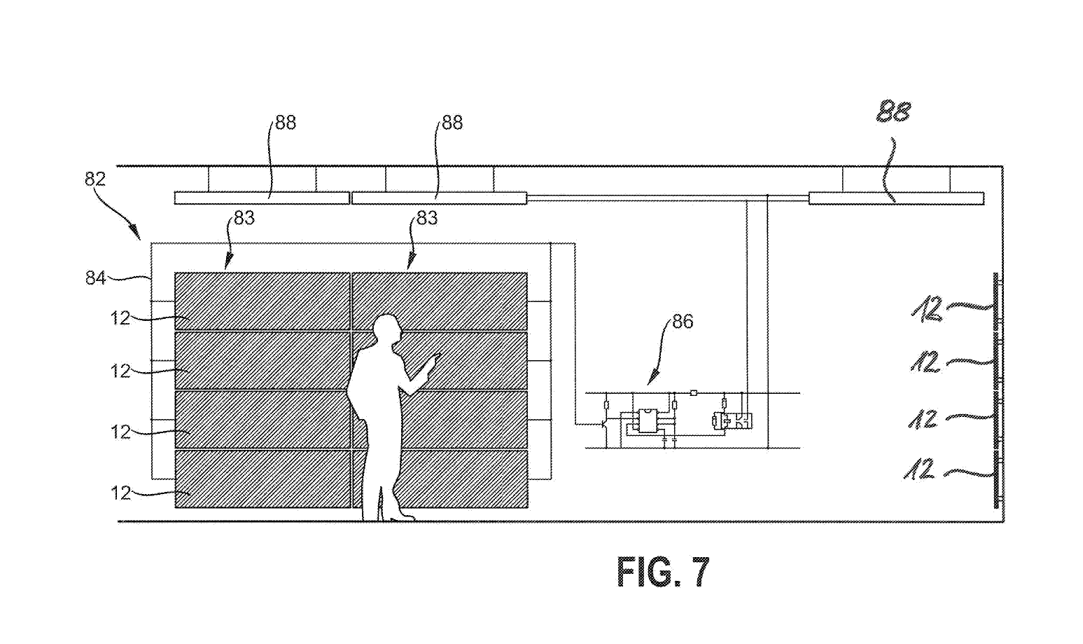

FIG. 7: an exemplary embodiment for a building installation and

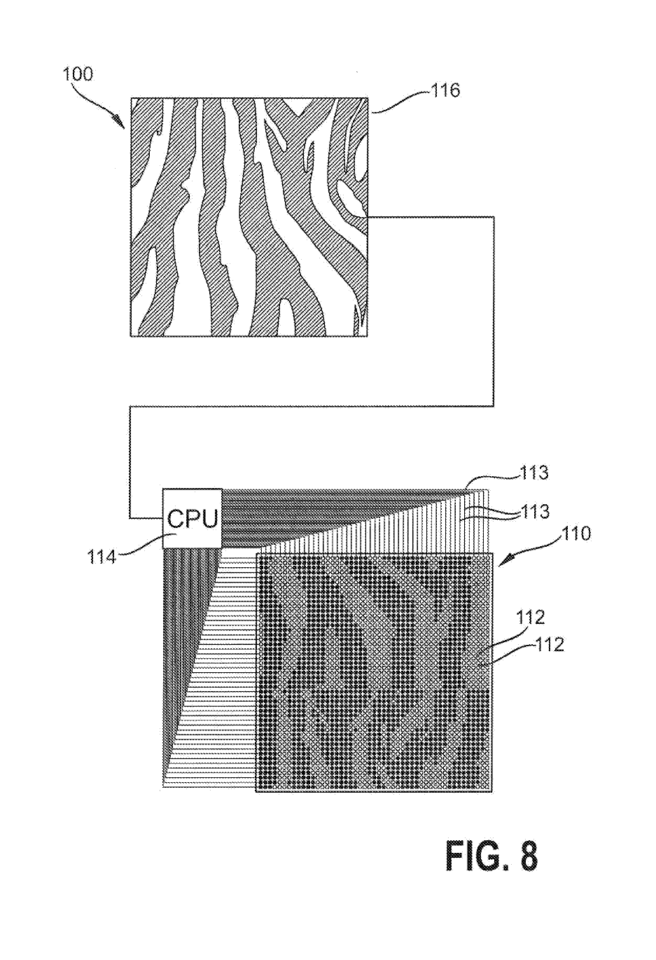

FIG. 8: an example of an optical design according to the invention.

According to FIG. 1, the electrical component according to the invention is composed of a section 12 made of concrete as a sensor and an electronics assembly 14, which is explained in more detail below. The sensor section 12 is configured box-shaped, thus comprising six outer surfaces, of which a rear surface 16, two side surfaces 18, 19 opposing one another and a component surface 20 are designated. The sensor section 12 consists essentially of conventional concrete. According to the invention, it additionally contains electrically conductive aggregates 22. The conventional components of the sensor section 12 made of concrete are known to be distributed as evenly as possible in order to provide the sensor section 12 a homogeneous structure. On the other hand, the electrically conductive aggregates 22 are unevenly distributed. Its density is particularly high in a region 24 near the surface, which directly adjoins the component surface 20. As viewed toward the rear surface 16, viewed from the component surface 20, the density of the electrically conductive aggregates 22 decreases at least substantially.

Two bolts project into the sensor section 12 as rod-shaped electrically conductive contacts 26, 28 and there into the region 24 near the surface. The contact 26 extends from the rear surface 16 to almost the component surface 20, the contact 28 extends from the side surface 18 in the region 24 near the surface. Both contacts 26, 28 represent an electrical interface to the region 24 near the surface, in which the electrically conductive aggregates 22 are present in a particularly high concentration. The contacts 26, 28 are connected via lines 30 to a current source 32 and a control device 34.

Due to its construction and its composition, the sensor section 12 on its component surface 20 provides a high conductivity of its concrete material. This electrical conductivity of its component surface 20 can be used to detect capacitance, charge or temperature, deformation or moisture changes influencing it. The component 10 can consequently act in any case as a capacitive, possibly as an inductive or resistive sensor. Due to its electrical conductivity according to the invention, the component surface 20 can be used as one of two electrodes of a capacitive sensor whose capacitance changes as soon as either an electrically conductive material or a dielectric is brought into the immediate vicinity. A person, or his hand or finger, which is or can reach the component surface 20 or in its immediate vicinity, can be used, for example, as the dielectric, an electrically weak or nonconductive, non-metallic substance whose charge carrier is generally not freely mobile. As a result, the capacitance of the section 24 near the surface changes. The control device 34 senses the change in capacitance there via the contacts 26, 28. Thereupon, the control device 34 outputs a signal which causes a desired effect with the contact of the component surface 20. The component 10 can thus serve as an approach or contact switch, with which, for example, a room lighting is switched, and a conventional light switch can be replaced. In contrast to the prior art, however, a conventional mechanical switch with moving parts is no longer required, which is subject to wear and, where appropriate, must be protected against environmental influences. Instead, the electrical component 10 according to the invention can be arranged as a switch in a conventional concrete wall without any movable parts. It is thus configured extremely robust and, in particular, vandalism-proof, whereby it is suitable, for example, as a switch in public space. Because it is produced from concrete, it can also be brought into almost any shape and design. In particular, it is not limited in terms of area, as a result of which switches can be designed with an actuation surface of virtually any desired size.

FIG. 2 shows a highly schematic sequence of production steps for producing a sensor section 12 according to the invention: a concrete matrix 42 is filled into a boxed-shaped formwork 40, open on the upper side, according to FIG. 2a, which contains a homogeneous concrete matrix of conventional aggregates, water and cement, and additional electrically conductive aggregates 22. Two electromagnets 46 are attached on a lower side 44 of the formwork 40 and are connected to a power supply 48.

After the concrete matrix 42 has been filled into the formwork 40 according to FIG. 2a, the electromagnets 46 are charged with current so that they form a magnetic field in the formwork 40. The electrically conductive aggregates 22 are initially largely freely movable in the still fresh concrete matrix 42. Under the influence of the magnetic field, they attach on the formwork 40 in two regions 23 above the magnets 46, so that they have a higher concentration there than in the remaining fresh concrete matrix 42. This process can further be supported by shaking the formwork 40 or the fresh concrete matrix 42, which is usually carried out for compacting concrete. Having the locally increased density of the aggregates 22 in the two regions 23, the concrete matrix 42 is allowed to cure. As soon as the electrical aggregates 22 have assumed their position and concentration according to FIG. 2b and the concrete matrix 42 has hardened so far that the aggregates of the matrix 42 can no longer be relocated, the power supply 48 is switched off.

After the concrete matrix 42 has hardened, the sensor section 12 is switched off, removed from the formwork 40 and reversed (see FIG. 2c). At its current component surface 20, the electrically conductive aggregates 22 concentrate with high density in the two regions 23. A sensor section 12 according to FIG. 1 can now be configured in each case where electrical contacts are mounted in the two regions 23 and are connected to an electronics assembly 14 according to FIG. 1.

In the region close to the surface 24 according to FIG. 1, the electrically conductive aggregates 22 are largely homogeneously present on the component surface 20 in an orthogonal plan view. The component surface 20 according to FIG. 2c, on the other hand, is not expected to have fully uniform conductivity, but shows two zones with high conductivity in those regions 23 near which the electromagnets 46 were placed during production. The increased density of the electrically conductive aggregates 22 can consequently be generated not only uniformly but also non-uniformly on the component surface 20, both in a direction from the component surface 20 to the rear surface 16, as well as non-uniformly in a direction between the side surfaces 18, 19.

A certain arrangement of permanent magnets or electromagnets is attached under the formwork. The conductive and magnetic particles of the concrete, i.e., the aggregates defining the conductivity, align themselves during the concreting process along the magnetic field lines. In its simplest form, the magnet system is attached under an existing formwork system, almost a ‘plug-under’, which does not require an adaptation of the formwork system. Forming systems with an integrated magnet system allow more precise control of the process.

The magnetic fields can be specifically controlled. Depending on the type, shape and strength of the magnet, the spread of the magnetic field changes. Neodymium magnet systems form higher and slimmer fields than ferromagnets. The field strengths of simple electromagnets are generally below permanent magnets. However, electromagnets can be produced in almost any size and are more calculable than permanent magnets because of the option of controlling them via design and current flow. A differentiated magnetic field can be produced through a targeted alignment of the magnetic poles so that magnetic fields and their paths can be selectively steered or redirected.

FIG. 3 shows a further option for producing a conductive concrete. The fresh concrete matrix 42 according to FIG. 3a also consists of substantially conventional components, and additional of steel fibers as electrically conductive aggregates 22. After mixing into a homo-geneous concrete matrix 42, it is introduced into a likewise box-shaped formwork 40 with opposing side surfaces 41 of FIG. 3a. In a subsequent manufacturing step, two electromagnets 46 are attached on the side surfaces 41 (see FIG. 3b). The fresh concrete matrix 42 is now exposed to magnetic pulses of the electromagnets 46. Depending on the strength and frequency of the magnetic impulses, they can either rotate and rectify in their orientation the electrically conductive aggregates 22 which are previously undirected or can even displaced them selectively in the concrete matrix 42 and can spatially concentrate them to form paths or strands.

The matrix 42 is subsequently allowed to harden in order to obtain the sensor element 12 according to FIG. 3c after the stripping. It shows regions 23 with high electrical conductivity, which lie on mutually opposite side surfaces 18, 19 of the sensor element 12, but deviating from the sensor element 12 according to FIG. 2c, are electrically conductively connected to one another by a section 25 made of conductive concrete.

If the opposing electromagnets 46 are attached to the formwork 40 according to FIG. 3 near a future component surface 20, a region near the surface 24 with increased electrical conductivity in the sensor element 12 can also be configured. Alternatively, regions of high density of electrical aggregates 22 in the sensor element 12 can additionally also be configured beyond the section 24 near the surface. Thus, for example, an electrical contacting by contacts 26, 28 (see FIG. 1) can be facilitated, namely, its spatial extent within the sensor element 12 can be shortened.

FIG. 4 shows a demonstration object for the use of the electrical component 10 according to the invention as an operating element: a block 50 of concrete produced and assembled according to the invention has a touch-sensitive surface 51. A high density of electrically conductive aggregates is present in a region near the surface below the surface 51, so that the surface 51 of the block 50 has a high electrical conductivity. On its underside, the block 50 has a likewise box-shaped recess 52. A U-shaped carrier 54 is attached, in which a light bulb 56 and its power supply 58 are attached. A control device 60 is inserted into a circuit for the electrical supply of the light bulb 56, which is in electrically conductive contact with the concrete block 50 via electrically conductive pins 62, or with the region near the surface under the surface 51. As soon as a user touches the surface 51 of the block 50, the control device 60 senses a change in capacitance on the surface 51 and turns on the power supply 58 of the light bulb 56. Further contact of the surface 51 actuates the control device 60 again, whereupon it switches off the power supply 58.

FIG. 5 shows a first possible application of the component 10 as a switch for a domestic installation. According to the invention, the sensor section 12 is part of a concrete wall 70 which separates two rooms from one another. The sensor section 12 is sunk into a position in the concrete wall 70 in which a user expects conventional light switches. The location of the sensor element 12 is indicated by a marking (not shown) on the concrete wall 70 so that the user can locate the sensor element 12 in the otherwise homogeneous wall 70. It is connected to a control device 34 with leads 30 shown in simplified form. On request, it switches on a room lighting 74, which is supplied with household electricity via a cable 75 under a ceiling 73.

If a user wishes to switch on the lighting 74, he touches the concrete wall 70 within the marking 72 and thus the sensor section 12. In the manner described in FIG. 1, the control device (not shown) senses the touch of the sensor section 12 and then switches on the supply current of the lighting 74. In principle, the lighting 74 can be switched off again. According to the invention, therefore, standard 220 V voltage of the supply current of the lighting 74 itself is not applied to the sensor section 12, that is to say in the area in which the power supply to the lighting 74 is switched. Instead, a substantially lower control current flows through the lead 30, which only detects a change in capacitance at the sensor element 12 and transmits it to the control device. Thus, the sensor element 12 according to the invention and the associated electrical unit are less dangerous than conventional switch arrangements for lighting.

FIG. 6 shows an alternative embodiment of a concrete wall to that in FIG. 5. Deviating from this embodiment, the concrete wall 76 is configured entirely from conductive concrete produced according to the invention. Its entire surface thus represents a sensor section 12 according to FIG. 1. It is connected to a control device 34 via contacts (not shown) and a lead 30, which in turn switches the supply current of a lighting 74.

No matter where a user touches the wall 76, the control 34 detects the capacitance change. It thereupon turns the power supply to the lighting 74 on or off. The function of the light switch is therefore applied to the complete surface of the concrete wall 76, so that a locally limited switch and a marking of a sensor element 12 (see FIG. 5) are no longer required.

FIG. 7 shows an exemplary embodiment for the use of the sensor element 12 according to the invention for switching a building installation. The large-area, rectangular sensor elements 12 are composed of a panel 82 of four rows and two columns. The panel 82 is attached vertically on the wall of an interior space and is connected to a control electronic unit 86 via leads 84. The control electronics unit 86 couples the panel 82 to the room installation from a lighting unit 88 and a ventilation unit 90. The control electronics unit 86 is configured and set up such that the sensor elements 12 in the left column 83 exclude a gain of electrical power during contact, while a touching of the sensor elements 12 of the right column 83 causes a reduction. Each row of sensor elements 12, in each case two sensor elements 12 arranged next to one another, are assigned to the same building installation, namely the uppermost row to the lighting unit 88, the underlying second row to the ventilation unit 90, the subsequent, underlying row can be assigned to a lead and the lowest row, for example, a loudspeaker device. The panel 82 thus represents a flat, unobstructed, but, based on its materials, easy-to-design operating unit for building installations, which can either be mounted separately and decorated or integrated into a building wall. The panel 82 can thus be used both as retrofitting and in the course of the original equipment of a building. Particularly as retrofitting, the panel 82 can show its strengths with regard to the low risk which comes from its leads 84.

The panel 82 is predestined for a modular design consisting of a plurality of sensor elements 12, which can either be provided with individual switching functions, as shown in FIG. 7, or together provide only a single switching function, for example, of six composite fields. Composite fields are in particular suitable for the configuration of dimming functions, according to which the left column 83 controls, e.g., “sweep” downward, the lighting unit 88 brighter, “sweep” upward, on the other hand, darker. The right column can be operated in the same way and an air conditioner can be set warmer or colder. The panel 82 can advantageously be configured as a prefabricated system, which is either mounted as an curtain-like element in front of an existing wall, as shown in FIG. 7, or is integrated as a finished part in a building construction.

FIG. 8 shows the basic structure of a formwork system 100 for the electromagnetic structuring of concrete components. The formwork system 100 comprises an electromagnetic square matrix 110 which can be mounted externally on or inside a formwork (not shown) for concrete components. It consists of 48×48 electromagnets 112, each of which is square. Each electromagnet 112 is electrically connected via lead 113 to a central computer unit (CPU) 114 and can be individually controlled from there, namely, switched on or off. The switched-on electromagnets 112 are black in FIG. 8 and the switched-off electromagnets 112 are shown in white. The central computer unit 114 controls the electromagnets 112 on the basis of a predetermined pattern 116, which converts them into a 48×48 grid and controls the local electromagnets 82 accordingly. The pattern 116 may have been created with one or every conventional graphics program and can be processed, as in the case of programming, for example, by a CNC-controlled milling cutter.

After introducing a fresh concrete matrix having an additive of electrically conductive and magnetic aggregates into the formwork, the central computer unit 114 switches on the black-marked electromagnets 112, so that they build up a magnetic field. A high concentration of electrically conductive aggregates thereupon queues up in the region of the switched-on electromagnets 112. This reflects the predetermined pattern 116 as a density distribution of electrically conductive aggregates in the concrete in the sense of FIG. 2. As a result, the concrete wall has an increased conductivity at its surface, which corresponds to the pattern 116. If the electrically conductive aggregates also have the property of coloring the concrete, the pattern 116 becomes apparent on the concrete surface and also visually reflects the regions of increased electrical conductivity.

Since the preceding electrical components or sensor elements described in detail are exemplary embodiments, they can be modified in a conventional manner by a person skilled in the art without departing from the scope of the invention. In particular, the concrete formations of the structure of the formwork can also follow a different form from that described here. In particular, the component can be configured in another form if this is necessary for reasons of space or design. Currently, concrete offers a variety of design possibilities here. Furthermore, the use of the indefinite articles “a” or “an” does not exclude the fact that the relevant features can also be present several times or more.

List of reference numbers

| | |
|---|---|
| 10 | Electrical component |
| 12 | Sensor element |
| 14 | Electronics assembly |
| 16 | Rear surface |
| 18, 19 | Side surfaces |
| 20 | Component surface |
| 22 | Electrically conductive aggregates |
| 24 | Region near the surface |
| 25 | Conductive section |
| 26 | Contact |
| 28 | Contact |
| 30 | Lead |
| 32 | Power source |
| 34 | Control unit |
| 40 | Formwork |
| 42 | Concrete matrix |
| 44 | Lower side |
| 46 | Electromagnet |
| 48 | Power supply |
| 50 | Block |
| 51 | Surface |
| 52 | Recess |
| 54 | Carrier |
| 56 | Light bulb |
| 58 | Power supply |
| 60 | Control device |
| 62 | Contact pin |
| 70 | Concrete wall |
| 72 | Lighting |
| 73 | Cover |
| 74 | Lighting |
| 75 | Cable |
| 76 | Conductive concrete wall |
| 82 | Panel |
| 83 | Column |
| 84 | Leads |
| 86 | Control electronics unit |
| 88 | Lighting unit |
| 90 | Ventilation unit |
| 100 | Formwork system |
| 110 | Electromagnetic matrix |
| 112 | Electromagnet |
| 113 | Lead |
| 114 | Central computer unit |
| 116 | Pattern |

1. Electrical component (10) which at least comprises a section (12) configured as a sensor (sensor section) made of concrete and which contains electrically conductive aggregates (22) which are present in a region (24) near the surface of at least one outer surface (20) of the section (12) in a higher spatial density than in the remaining section (12).

2. Electrical component according to the preceding claim, characterized by a capacitively, inductively or resistively acting sensor section (12).

3. Electrical component according to one of the preceding claims, characterized in that the electrically conductive aggregates (22) are unevenly distributed in a plan view on the outer surface (20) section (12) configured as a sensor.

4. Electrical component according to one of the preceding claims, characterized by electrical interfaces (26; 28) introduced into the region (24) near the surface of the sensor section (12) to an electrical circuit (14).

5. Electrical component according to one of the preceding claims, having a manually actuable sensor section (12), characterized by an optically perceptible marking generated by means of the electrically conductive aggregates (22) on a surface of the sensor section (12).

6. Electrical component according to one of the preceding claims for detecting variable component characteristics of a concrete component, characterized by a sensor made of electrically conductive concrete arranged monolithically in a component to be sensed.

7. Method for the production of a proximity-sensitive or contact-sensitive concrete component, having the following steps:
a) Preparing a concrete matrix for fresh concrete,
b) Admixing electrically conductive aggregates into the fresh concrete,
c) Introducing the fresh concrete into a formwork for the component to be produced,
d) Increasing the spatial density of at least a part of the electrically conductive aggregates (in a defined region adjacent to) a component surface (outer surface)
e) Curing the concrete component.

8. Method according to the above method claim, characterized in that in step b) at least a part of aggregates which can be influenced by magnetization is admixed, and a magnetic field is established on the formwork in step d).

9. Method according to the above method claim, characterized in that a pulsed, in particular non-continuous, magnetic field is established.

10. Method according to one of the above method claims, characterized in that the electrically conductive aggregates are distributed unevenly in a plan view on the component surface.

11. Method according to one of the above method claims, characterized in that electrical contacts are mounted in the hardened concrete component before step c) or after step e).

12. Method for the production of a concrete component which is proximity-sensitive or contact-sensitive, wherein the electrical component is concreted in at least two phases, namely in any case in the temporally first phase in a manner known per se and in any case in the temporally last phase according to a method according to one of the above method claims 7 to 11.

13. Method for producing a concrete component which is proximity-sensitive or contact-sensitive, wherein the electrical component is produced at least as a precast concrete part and subsequently is applied to a concrete component.

14. Use of an electrical component of electrically conductive concrete section as a switching or control element according to one of claims 1 to 6 for switching or controlling electrical current and/or for detecting variable component characteristics.

15. Method for determining the position of a mobile communication device in a building having electrical components according to one of the above device claims and having a central computer which stores location information for each electrical component within the building and a further data record in each case, in the following steps:
a) Making contact with the central computer by the communication device,
b) Requesting to actuate the electrical component,
c) Detecting an actuation of the electrical component,
d) Transferring the further data record assigned to the actuated electrical component to the communication device.
